(19) United States
(12) Patent Application Publication
(10) Pub. No.: US 2018/0145148 A1
(43) Pub. Date: May 24, 2018

(54) COMPOUND SEMICONDUCTOR DEVICE

(71) Applicant: FUJITSU LIMITED, Kawasaki-shi (JP)

(72) Inventor: Atsushi Yamada, Hiratsuka (JP)

(73) Assignee: FUJITSU LIMITED, Kawasaki-shi (JP)

(21) Appl. No.: 15/717,033

(22) Filed: Sep. 27, 2017

(30) Foreign Application Priority Data
Nov. 22, 2016 (JP) 2016-227024

(51) Int. Cl. H01L 29/66; H01L 29/205; H01L 29/778

(52) U.S. Cl. CPC H01L 29/66431; H01L 29/7786; H01L 29/205

(57) ABSTRACT

A compound semiconductor device includes: a substrate; a channel layer formed over the substrate; a spacer structure formed over the channel layer; a barrier layer of Inₓ₁Al_{y1}Ga_{1-x1-y1}N (0≤x1<0.20, 0<y1≤1) formed over the spacer structure; and a gate electrode, a source electrode, and a drain electrode which are formed over the barrier layer. The spacer structure includes: a first spacer layer of Alₓ₂Ga₁₋ₓ₂N (0<x2<1) formed over the channel layer; and a second spacer layer of GaN formed over the first spacer layer.

### CROSS-REFERENCE TO RELATED APPLICATIONS

This application is based upon and claims the benefit of priority of the prior Japanese Patent Application No. 2016-227024, filed on Nov. 22, 2016, the entire contents of which are incorporated herein by reference.

### FIELD

The embodiments discussed herein are directed to a compound semiconductor device and so on.

### BACKGROUND

Nitride semiconductors have characteristics such as high saturation electron velocity and a wide band gap. Accordingly, various studies are being made on the application of nitride semiconductors to high withstand voltage and high power semiconductor devices utilizing these characteristics. For example, a band gap of GaN, which is a kind of a nitride semiconductor, is 3.4 eV, which is larger than a band gap of Si (1.1 eV) and a band gap of GaAs (1.4 eV). Accordingly, GaN has high breakdown electric field intensity and is very promising as a material of power source semiconductor devices of which a high-voltage operation and high power are required.

As a semiconductor device using nitride semiconductors, many reports have been made about field-effect transistors, in particular, high electron mobility transistors (HEMT). As HEMT using the nitride semiconductors, HEMT using GaN as a channel layer and using AlGaN or InAlN as a barrier layer has been known. In particular, HEMT using InAlN as the barrier layer has recently been drawing attention. InAlN has stronger spontaneous polarization than AlGaN and thus facilitates inducing high-concentration two-dimensional electron gas (2DEG). InAlN is in lattice match with GaN when its In composition is 17% to 18%. Therefore, access resistance between a source and a gate and access resistance between the gate and a drain can be made lower than in HEMT using AlGaN as a barrier layer. Further, the thinner the barrier layer is, the shorter the distance between a gate electrode and 2DEG is, and accordingly the higher the obtained mutual conductance (gm) is.

However, alloy scattering in InAlN is larger than that in AlGaN. Accordingly, when the GAN channel layer is in direct contact with the InAlN barrier layer, the alloy scattering greatly lowers mobility of 2DEG. It is possible to reduce the alloy scattering by providing an AlN spacer layer between the channel layer and the barrier layer.

However, an AlN layer is difficult to grow flat, and accordingly, in HEMI including the AlN spacer layer, surface flatness of the barrier layer is quite low. As the surface flatness of the barrier layer is lower, a larger gate leakage current flows. Using AlGaN instead of AlN improves the surface flatness of the barrier layer, but still cannot achieve sufficient flatness.
Patent Literature 1: Japanese Laid-Open Patent Publication No. 2013-179128
Patent Literature 2: Japanese Laid-Open Patent Publication No. 2012-256706
Non-Patent Literature 1: M. Gonschorek, J.-F. Carlin, E. Feltin, M. A. Py, and N. Grandjean, Appl. Phys. Lett. 89, 062106 (2006)
Non-Patent Literature 2: A. Yamada, T. Ishiguro, J. Kotani, S. Tomabechi, N. Nakamura, and K. Watanabe, Jpn. J. Appl. Phys., 55, 05FK03 (2016)

### SUMMARY

According to an aspect of the embodiments, a compound semiconductor device includes: a substrate; a channel layer formed over the substrate; a spacer structure formed over the channel layer; a barrier layer of Inₓ₁Al_{y1}Ga_{1-x1-y1}N (0≤x1<0.20, 0<y1≤1) formed over the spacer structure; and a gate electrode, a source electrode, and a drain electrode which are formed over the barrier layer, wherein the spacer structure includes: a first spacer layer of Alₓ₂Ga₁₋ₓ₂N (0<x2<1) formed over the channel layer; and a second spacer layer of GaN formed over the first spacer layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a view illustrating an atomic force microscope (AFM) image of a surface of an InAlN layer formed on an AlGaN layer with a GaN layer therebetween;

FIG. 1B is a view illustrating an AFM image of a surface of an InAlN layer formed directly on an AlGaN layer;

FIG. 2 is a chart illustrating a relation between a thickness of a GaN layer and sheet resistance;

FIG. 3 is a chart illustrating a relation between a number of stacks and sheet resistance;

FIG. 4A is a view illustrating an AFM image of a surface of an InAlN layer when the number of the stacks is one;

FIG. 4B is a view illustrating an AFM image of a surface of an InAlN layer when the number of the stacks is two;

FIG. 5 is a view illustrating a compound semiconductor device according to a first embodiment;

FIG. 6A to FIG. 6F are process-by-process sectional views illustrating a method of manufacturing the compound semiconductor device according to the first embodiment;

FIG. 7 is a view illustrating a compound semiconductor device according to a second embodiment;

FIG. 8A to FIG. 8C are process-by-process sectional views illustrating a method of manufacturing the compound semiconductor device according to the second embodiment;

FIG. 9 is a view illustrating a compound semiconductor device according to a third embodiment;

FIG. 10A to FIG. 10F are process-by-process sectional views illustrating a method of manufacturing the compound semiconductor device according to the third embodiment;

FIG. 11 is a view illustrating a compound semiconductor device according to a fourth embodiment;

FIG. 12 is a view illustrating a compound semiconductor device according to a fifth embodiment;

FIG. 13A and FIG. 13B are process-by-process sectional views illustrating a method of manufacturing the compound semiconductor device according to the fifth embodiment;

FIG. 14 is a view illustrating a compound semiconductor device according to a sixth embodiment;

FIG. 15 is a view illustrating a compound semiconductor device according to a seventh embodiment;

FIG. 16 is a view illustrating a compound semiconductor device according to an eighth embodiment;

FIG. 17 is a view illustrating a discrete package according to a ninth embodiment;

FIG. 18 is a wiring diagram illustrating a PFC circuit according to a tenth embodiment;

FIG. 19 is a wiring diagram illustrating a power supply apparatus according to an eleventh embodiment; and

FIG. 20 is a wiring diagram illustrating an amplifier according to a twelfth embodiment.

### DESCRIPTION OF EMBODIMENTS

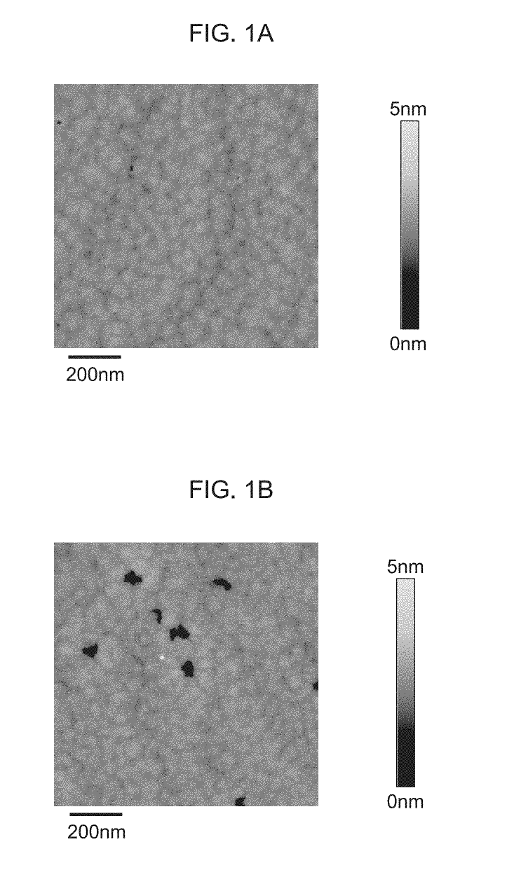

The inventor of the present application has repeated studious studies in order to solve the aforesaid problem. As a result, it has been found out that disposing a GaN layer between an AlGaN spacer layer and an InAlN barrier layer makes it possible to greatly improve surface flatness of the barrier layer. FIG. 1A and FIG. 1B are views illustrating atomic force microscope (AFM) images of surfaces of barrier layers. FIG. 1A illustrates the AFM image of the surface of an InAlN layer formed on an AlGaN layer with a GaN layer therebetween, and FIG. 1B illustrates the AFM image of the surface of an InAlN layer formed directly on an AlGaN layer. No pit was observed on the surface of the InAlN layer formed on the AlGaN layer with the GaN layer therebetween as illustrated in FIG. 1A, while some pits were observed on the surface of the InAlN layer formed directly on the AlGaN layer as illustrated in FIG. 1B.

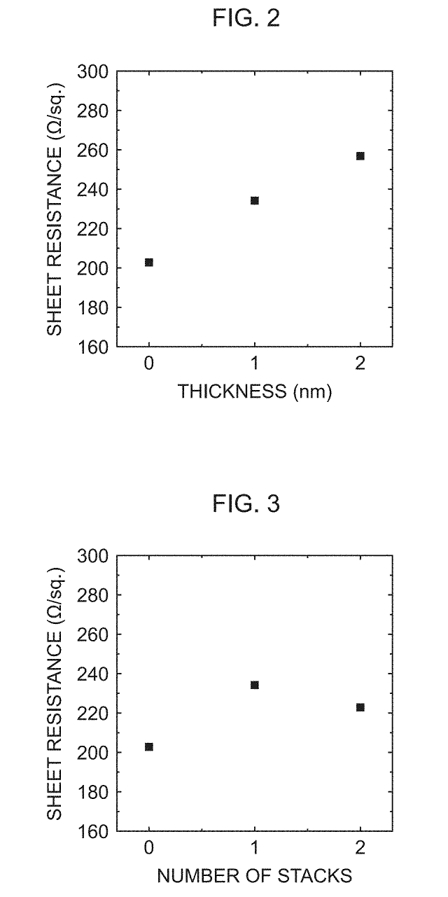

It has also become clear that sheet resistance is higher as the GaN layer between the AlGaN layer and the InAlN layer is thicker. FIG. 2 illustrates a relation between the thickness of the GaN layer and the sheet resistance. From the result illustrated in FIG. 2, the thickness of the GaN layer is preferably 2 nm or less, and more preferably 1 nm less from a viewpoint of a reduction of the sheet resistance.

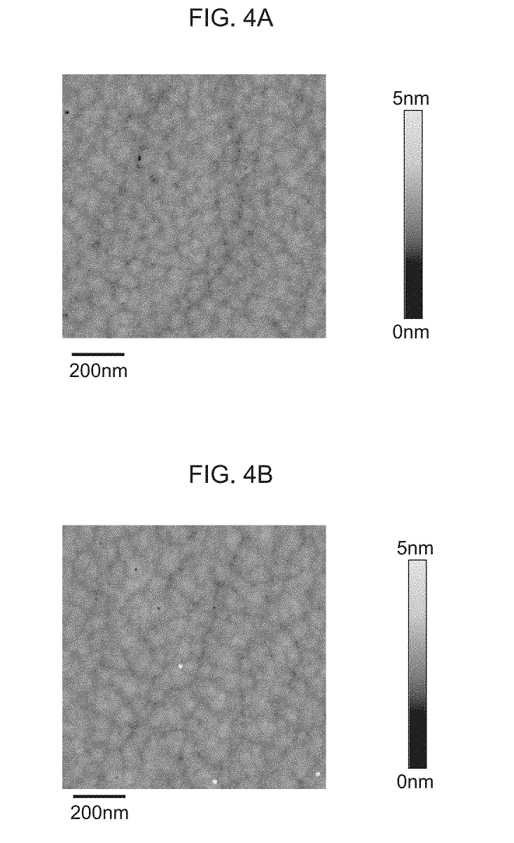

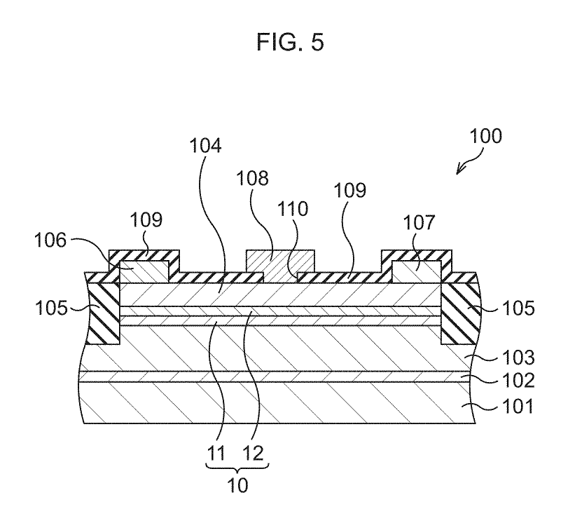

It has also become clear that the sheet resistance is lower when the number of stacks of the AlGaN layer and the GaN layer between a GaN channel layer and the InAlN barrier layer is two, than when the number of the stacks is one. FIG. 3 illustrates a relation between the number of the stacks and the sheet resistance. A possible reason for this tendency is that the AlGaN layer also functions as a barrier layer. Thus, the sheet resistance may be lower as the number of the stacks is larger. Incidentally, even if the number of the stacks increases, the flatness of the surface of the InAlN barrier layer is kept good. FIG. 4A illustrates an AFM image of the surface of the InAlN layer when the number of the stacks is one, and FIG. 4B illustrates an AFM image of the surface of the InAlN layer when the number of the stacks is two. As illustrated in FIG. 4A and FIG. 4B, pits were observed on the surface of the InAlN layer neither when the number of the stacks is one nor when it is two.

As a result of studious studies based on these findings, the inventor of the present application has reached the following embodiments. Hereinafter, the embodiments will be specifically described with reference to the attached drawings.

### First Embodiment

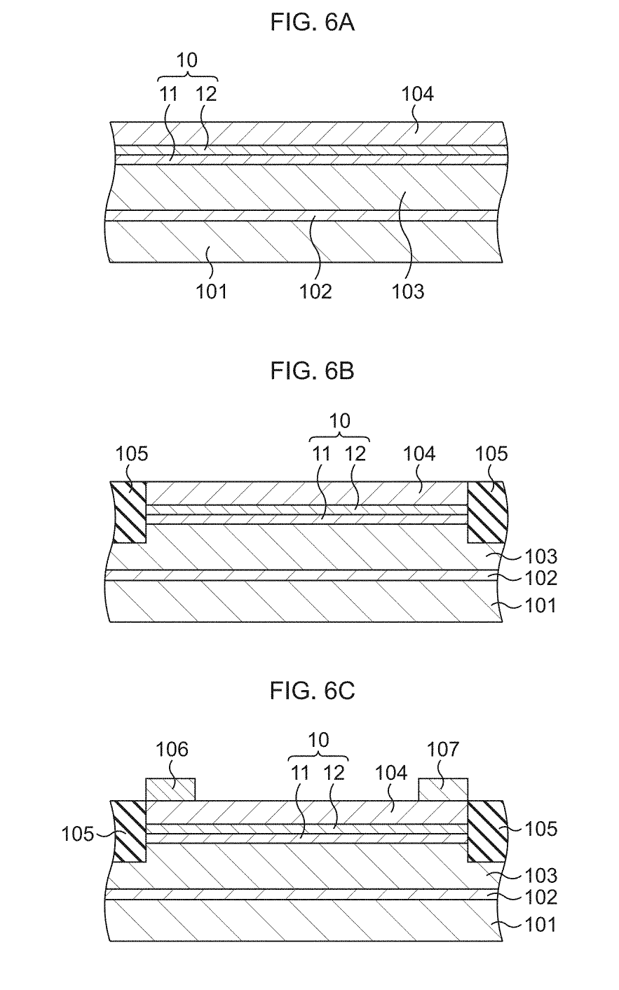

First, a first embodiment will be described. The first embodiment relates to an example of HEMT including a compound semiconductor epitaxial substrate. FIG. 5 is a view illustrating a compound semiconductor device according to the first embodiment.

As illustrated in FIG. 5, a compound semiconductor device 100 according to the first embodiment includes a substrate 101, a nucleation layer 102 over the substrate 101, a channel layer 103 over the nucleation layer 102, a spacer structure 10 over the channel layer 103, and a barrier layer 104 over the spacer structure 10.

The substrate 101 is a semi-insulating SiC substrate, for instance. The nucleation layer 102 is an AlN layer having a thickness of, for example, about 100 nm. The channel layer 103 is a GaN layer (i-GaN layer) having a thickness of, for example, about 3 μm and not containing intentionally doped impurities. The barrier layer 104 is an Inₓ₁Al_{y1}Ga_{1-x1-y1}N (0≤x1<0.20, 0<y1≤1) layer (i-InAlGaN layer) having a thickness of, for example, about 10 nm and not containing intentionally doped impurities. A value of x1 is preferably 0.2 or less, and a combination of the value of x1 and a value of y1 is 0.17 to 0.18 and 0.83 to 0.82, for instance. The spacer structure 10 includes a first spacer layer 11 and a second spacer layer 12 over the first spacer layer 11. The first spacer layer 11 is an Alₓ₂Ga₁₋ₓ₂N (0<x2<1) layer (i-AlGaN layer) having a thickness of, for example, about 1 nm and not containing intentionally doped impurities, and the second spacer layer 12 is a GaN layer (i-GaN layer) having a thickness of, for example, about 1 nm and not containing intentionally doped impurities. A value of x2 is preferably 0.9 or less, more preferably 0.8 or less, and still more preferably 0.7 or less. In view of reducing internal stress, the thickness of the first spacer layer 11 is preferably 5 nm or less, and more preferably 2 nm less. In view of reducing sheet resistance, the thickness of the second spacer layer 12 is preferably 2 nm or less, and more preferably 1 nm or less. The first spacer layer 11, the second spacer layer 12, or the barrier layer 104, or any combination thereof may be doped with n-type impurities, for example, Si. When the channel layer 103 is the GaN layer, the barrier layer 104 is substantially in lattice match with the channel layer 103, if the barrier layer 104 is an In_{0.17-0.18}Al_{0.83-0.82}N layer.

An element isolation region 105 demarcating an element region is formed in a stack of the channel layer 103, the spacer structure 10, and the barrier layer 104. The compound semiconductor device 100 includes a source electrode 106 and a drain electrode 107 on the barrier layer 104 in the element region. An insulating film 109 covering the source electrode 106 and the drain electrode 107 is formed over the barrier layer 104. The insulating film 109 has a thickness of 2 nm to 500 nm, for example, about 100 nm, and functions as a passivation film. A material of the insulating film 109 is, for example, an oxide, a nitride, or an oxynitride of Si, Al, Hf, Zr, Ti, Ta, or W, and is preferably silicon nitride. The insulating film 109 has an opening 110 (gate recess) between the source electrode 106 and the drain electrode 107. The compound semiconductor device 100 includes a gate electrode 108 in contact with the barrier layer 104 through the opening 110. The source electrode 106 and the drain electrode 107 each include, for example, a Ta film and an Al film over the Ta film and are in ohmic contact with the barrier layer 104. The gate electrode 108 includes, for example, a Ni film and a Au film over the Ni film and is in Schottky contact with the barrier layer 104.

In the first embodiment, the substrate 101, the nucleation layer 102, the channel layer 103, the spacer structure 10, and the barrier layer 104 are included in the compound semiconductor epitaxial substrate.

In the first embodiment, the spacer structure 10 includes the second spacer layer 12. This makes the barrier layer 104 excellent in surface flatness as is apparent from the above-described experiment result. The improved flatness leads to a reduction of a gate leakage current.

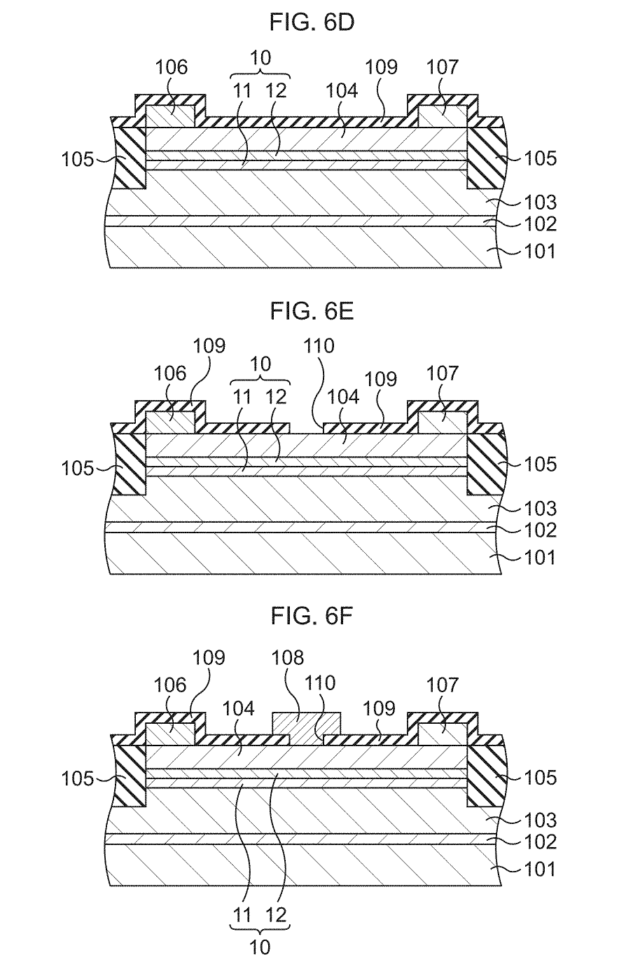

Next, a method of manufacturing the compound semiconductor device according to the first embodiment will be described. FIG. 6A to FIG. 6F are process-by-process sectional views illustrating the method of manufacturing the compound semiconductor device according to the first embodiment.

First, as illustrated in FIG. 6A, the nucleation layer 102, the channel layer 103, the first spacer layer 11, the second spacer layer 12, and the barrier layer 104 are formed over the substrate 101. The nucleation layer 102, the channel layer 103, the first spacer layer 11, the second spacer layer 12, and the barrier layer 104 may be formed by, for example, a crystal growth method such as a metal organic vapor phase epitaxy (MOVPE) method or a molecular beam epitaxy (MBE) method. When the MOVPE method is used for the formation, a raw material gas is, for example, mixed gas of trimethylaluminum (TMAl) gas, trimethylgalium (TMGa) gas, trimethylindium (TMIn) gas, and ammonia (NH₃) gas, and carrier gas is nitrogen (N₂) gas or hydrogen (H₂) gas. Whether to supply the TMAl gas, the TMGa gas, and the TMIn gas and their flow rates are appropriately controlled according to a compound semiconductor layer that is to be formed. For example, growth pressure is about 1 kPa to about 100 kPa, and growth temperature is about 700° C. to about 1200° C.

Then, as illustrated in FIG. 6B, the element isolation region 105 that demarcates the element region are formed in the stack of the channel layer 103, the spacer structure 10, and the barrier layer 104. In the formation of the element isolation region 105, a photoresist pattern exposing a region where to form the element isolation region 105 is formed over the barrier layer 104, and ions of Ar or the like are implanted with this pattern as a mask, for instance. Dry etching using chlorine-based gas may be performed with this pattern as an etching mask.

Thereafter, as illustrated in FIG. 6C, the source electrode 106 and the drain electrode 107 are formed over the barrier layer 104 in the element region. The source electrode 106 and the drain electrode 107 may be formed by, for example, a lift-off method. Specifically, a photoresist pattern exposing a region where to form the source electrode 106 and a region where to form the drain electrode 107 and covering the other region is formed, a metal film is formed by a vapor deposition method with this pattern as a deposition mask, and this pattern is removed together with a part of the metal film on the pattern. In the formation of the metal film, for example, the Ta film with an about 20 nm thickness is formed and the Al film with an about 200 nm thickness is formed over the Ta film. Then, heat treatment such as rapid thermal annealing (RTA) is performed at 400° C. to 1000° C. (for example, 550° C.) in, for example, a N₂ gas atmosphere to establish the ohmic contact.

Subsequently, as illustrated in FIG. 6D, the insulating film 109 is formed over the barrier layer 104 so as to cover the source electrode 106 and the drain electrode 107. The insulating film 109 may be formed by, for example, a plasma enhanced chemical vapor deposition (PECVD) method, an atomic layer deposition (ALD) method, or a sputtering method. When a silicon nitride film is formed as the insulating film 109, the PECVD method is preferable.

Then, as illustrated in FIG. 6E, the opening 110 is formed in the insulating film 109. In the formation of the opening 110, a resist pattern exposing a region where to form the opening 110 is formed on the insulating film 109, and the insulating film 109 is etched. The etching is, for example, dry etching using fluorine-based gas or chlorine-based gas or wet etching using hydrofluoric acid or buffered hydrofluoric acid.

Thereafter, as illustrated in FIG. 6F, the gate electrode 108 is formed on the insulating film 109 so as to be in contact with the barrier layer 104 through the opening 110. The gate electrode 108 may be formed by, for example, a lift-off method. Specifically, a photoresist pattern exposing a region where to form the gate electrode 108 is formed, a metal film is formed by a vapor deposition method with this pattern as a deposition mask, and this pattern is removed together with a part of the metal film on the pattern. In the formation of the metal film, for example, the Ni film with an about 30 nm thickness is formed and thereafter the Au film with an about 400 nm thickness is formed.

Then, a protective film, wiring, and others are formed as required to complete the compound semiconductor device.

### Second Embodiment

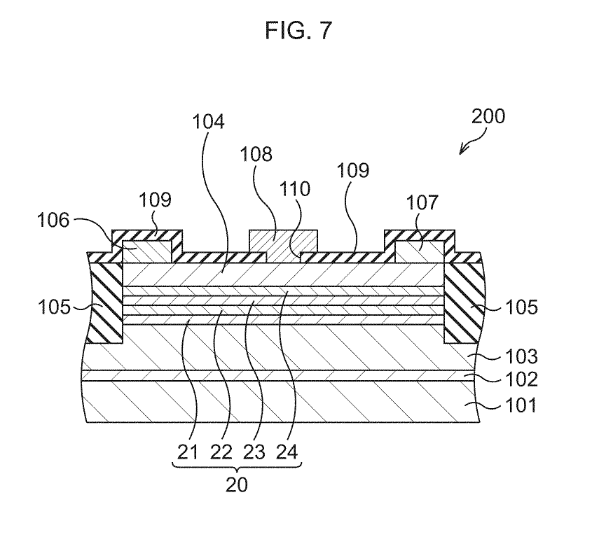

Next, a second embodiment will be described. The second embodiment relates to an example of HEMT including a compound semiconductor epitaxial substrate. FIG. 7 is a view illustrating a compound semiconductor device according to the second embodiment.

As illustrated in FIG. 7, a compound semiconductor device 200 according to the second embodiment includes a spacer structure 20 instead of the spacer structure 10, between the channel layer 103 and the barrier layer 104. The spacer structure 20 includes a first spacer layer 21, a second spacer layer 22 over the first spacer layer 21, a third spacer layer 23 over the second spacer layer 22, and a fourth spacer layer 24 over the third spacer layer 23. The first spacer layer 21 and the third spacer layer 23 are each an Alₓ₂Ga₁₋ₓ₂N (0<x2<1) layer (i-AlGaN layer) having a thickness of, for example, about 1 nm and not containing intentionally doped impurities, and the second spacer layer 22 and the fourth spacer layer 24 are each a GaN layer (i-GaN layer) having a thickness of, for example, about 1 nm and not containing intentionally doped impurities. A value of x2 is preferably 0.9 or less, more preferably 0.8 or less, and still more preferably 0.7 or less. The first spacer layer 21, the second spacer layer 22, the third spacer layer 23, or the fourth spacer layer 24, or any combination thereof may be doped with n-type impurities, for example, Si. The other structure is the same as that of the first embodiment.

In the second embodiment, the substrate 101, the nucleation layer 102, the channel layer 103, the spacer structure 20, and the barrier layer 104 are included in the compound semiconductor epitaxial substrate.

In the second embodiment, the spacer structure 20 includes the second spacer layer 22 and the fourth spacer layer 24. This makes the barrier layer 104 excellent in surface flatness as is apparent from the above-described experiment result. The improved flatness leads to a reduction of a gate leakage current. Not only the stack of the first spacer layer 21 and the second spacer layer 22 but also a stack of the third spacer layer 23 and the fourth spacer layer 24 is included. The stack of the third spacer layer 23 and the fourth spacer layer 24 is equivalent to the stack of the first spacer layer 21 and the second spacer layer 22, and it can be said that in the second embodiment, two stacks of the first spacer layer 21 and the second spacer layer 22 are included. This makes it possible to reduce sheet resistance more than the first embodiment as is apparent from the above-described experiment result. Incidentally, three or more stacks of the first spacer layer 21 and the second spacer layer 22 may be included.

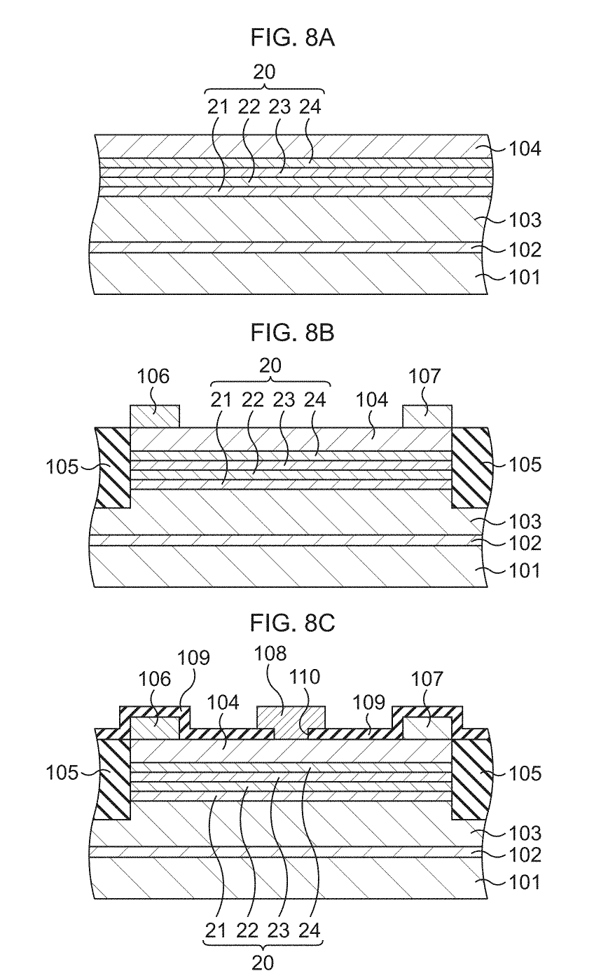

Next, a method of manufacturing the compound semiconductor device according to the second embodiment will be described. FIG. 8A to FIG. 8C are process-by-process sectional views illustrating the method of manufacturing the compound semiconductor device according to the second embodiment.

First, as illustrated in FIG. 8A, the nucleation layer 102, the channel layer 103, the first spacer layer 21, the second spacer layer 22, the third spacer layer 23, the fourth spacer layer 24, and the barrier layer 104 are formed over the substrate 101. The nucleation layer 102, the channel layer 103, the first spacer layer 21, the second spacer layer 22, the third spacer layer 23, the fourth spacer layer 24, and the barrier layer 104 may be formed by, for example, a crystal growth method such as a MOVPE method or a MBE method.

Then, as illustrated in FIG. 8B, the element isolation regions 105, the source electrode 106, and the drain electrode 107 are formed in the same manners as in the first embodiment. Thereafter, as illustrated in FIG. 8C, the insulating film 109, the opening 110, and the gate electrode 108 are formed in the same manners as in the first embodiment.

Then, a protective film, wiring, and others are formed as required to complete the compound semiconductor device.

### Third Embodiment

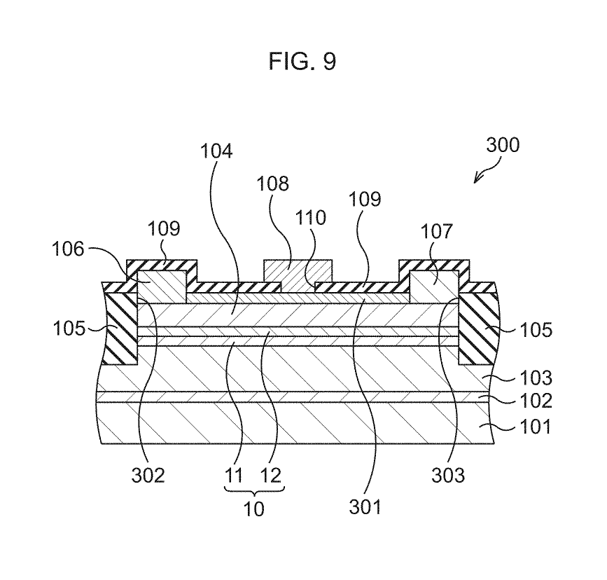

Next, a third embodiment will be described. The third embodiment relates to an example of HEMT including a compound semiconductor epitaxial substrate. FIG. 9 is a view illustrating a compound semiconductor device according to the third embodiment.

As illustrated in FIG. 9, a compound semiconductor device 300 according to the third embodiment includes a cap layer 301 over the barrier layer 104. The cap layer 301 is an Alₓ₃Ga₁₋ₓ₃N (0≤x3<1) layer (i-AlGaN layer) having a thickness of, for example, about 2 nm and not containing intentionally doped impurities. A value of x3 is 0, for instance. An opening 302 for source and an opening 303 for drain are formed in the cap layer 301. The source electrode 106 is in contact with the barrier layer 104 through the opening 302, and the drain electrode 107 is in contact with the barrier layer 104 through the opening 303. The other structure is the same as that of the first embodiment.

In the third embodiment, the substrate 101, the nucleation layer 102, the channel layer 103, the spacer structure 10, the barrier layer 104, and the cap layer 301 are included in the compound semiconductor epitaxial substrate.

The third embodiment achieves stabler characteristics because of including the cap layer 301. For example, the oxidation of the barrier layer 104 is more surely suppressed, leading to high reliability.

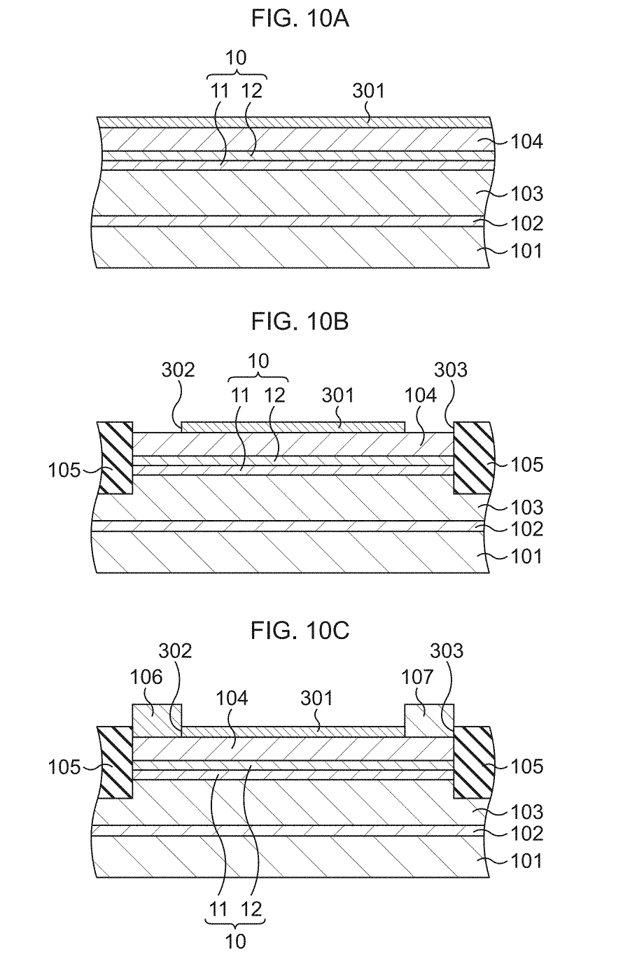

Next, a method of manufacturing the compound semiconductor device according to the third embodiment will be described. FIG. 10A to FIG. 10F are process-by-process sectional views illustrating the method of manufacturing the compound semiconductor device according to the third embodiment.

First, as illustrated in FIG. 10A, the nucleation layer 102, the channel layer 103, the first spacer layer 11, the second spacer layer 12, the barrier layer 104, and the cap layer 301 are formed over the substrate 101. The nucleation layer 102, the channel layer 103, the first spacer layer 11, the second spacer layer 12, the barrier layer 104, and the cap layer 301 may be formed by, for example, a crystal growth method such as a MOVPE method or a MBE method.

Then, as illustrated in FIG. 10B, the element isolation region 105 is formed in the same manner as in the first embodiment. Thereafter, the opening 302 and the opening 303 are formed in the cap layer 301. In the formation of the opening 302 and the opening 303, a resist pattern exposing regions where to form the opening 302 and the opening 303 is formed over the cap layer 301, and the cap layer 301 is etched. The etching is, for example, dry etching using chlorine-based gas.

Subsequently, as illustrated in FIG. 10C, the source electrode 106 is formed so as to be in contact with the barrier layer 104 through the opening 302, and the drain electrode 107 is formed so as to be in contact with the barrier layer 104 through the opening 303. The source electrode 106 and the drain electrode 107 may be formed by a lift-off method as in the first embodiment.

Then, in the same manners as in the first embodiment, the insulating film 109 is formed over the cap layer 301 as illustrated in FIG. 10D, the opening 110 is formed in the insulating film 109 as illustrated in FIG. 10E, and the gate electrode 108 is formed as illustrated in FIG. 10F.

Then, a protective film, wiring, and others are formed as required to complete the compound semiconductor device.

### Fourth Embodiment

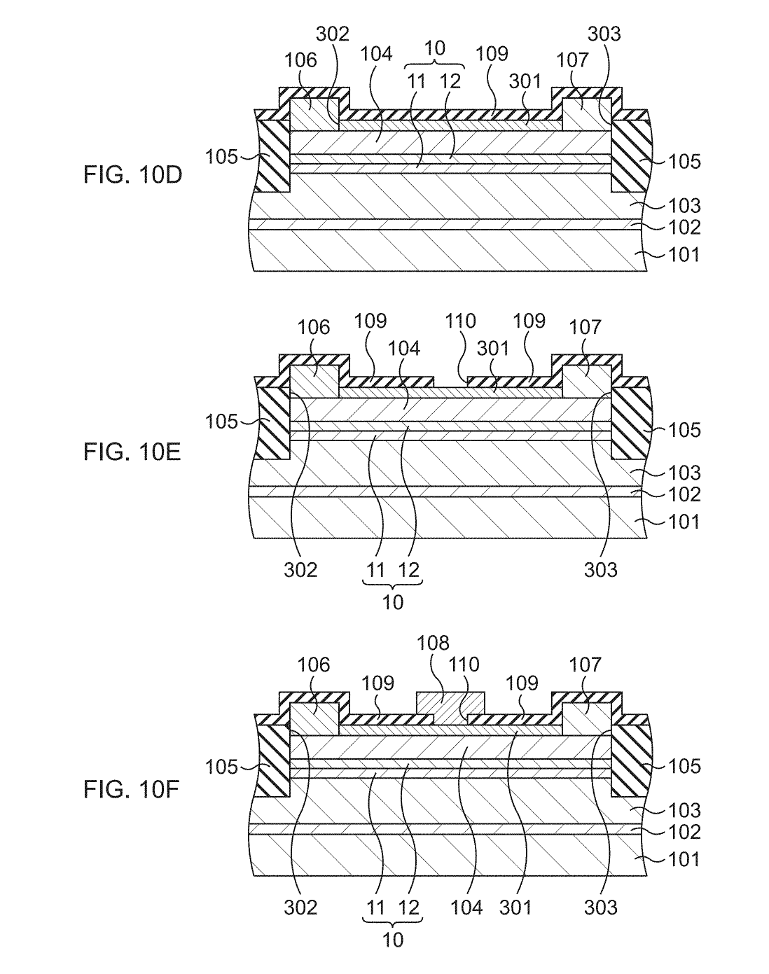

Next, a fourth embodiment will be described. The fourth embodiment relates to an example of HEMT including a compound semiconductor epitaxial substrate. FIG. 11 is a view illustrating a compound semiconductor device according to the fourth embodiment.

As illustrated in FIG. 11, a compound semiconductor device 400 according to the fourth embodiment includes the cap layer 301 over the barrier layer 104 as in the third embodiment. The other structure is the same as that of the second embodiment. That is, the compound semiconductor device 400 includes the spacer structure 20.

In the fourth embodiment, the substrate 101, the nucleation layer 102, the channel layer 103, the spacer structure 20, the barrier layer 104, and the cap layer 301 are included in the compound semiconductor epitaxial substrate.

According to the fourth embodiment, it is possible to reduce a gate leakage current, reduce sheet resistance, and obtain excellent reliability.

### Fifth Embodiment

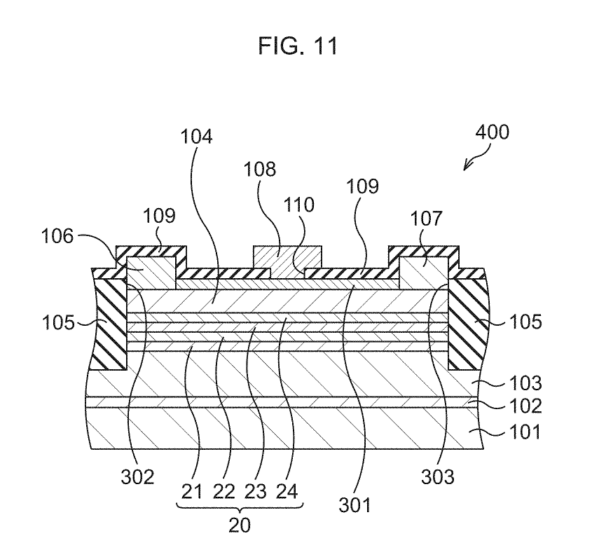

Next, a fifth embodiment will be described. The fifth embodiment relates to an example of HEMT including a compound semiconductor epitaxial substrate. FIG. 12 is a view illustrating a compound semiconductor device according to the fifth embodiment.

As illustrated in FIG. 12, a compound semiconductor device 500 according to the fifth embodiment includes, over the barrier layer 104, an insulating film 509 instead of the insulating film 109. The insulating film 509 has a thickness of 2 nm to 200 nm, for example, about 20 nm, and functions as a gate insulating film. A material of the insulating film 509 is, for example, an oxide, a nitride, or an oxynitride of Si, Al, Hf, Zr, Ti, Ta, or W and is preferably aluminum oxide. Without a gate recess formed in the insulating film 509, the gate electrode 108 is formed on the insulating film 509 to be insulated from the barrier layer 104. The other structure is the same as that of the first embodiment.

In the fifth embodiment, the substrate 101, the nucleation layer 102, the channel layer 103, the spacer structure 10, and the barrier layer 104 are included in the compound semiconductor epitaxial substrate.

The fifth embodiment adopts a MIS (metal-insulator-semiconductor) gate structure, while the first embodiment adopts the Schottky gate structure. Therefore, according to the fifth embodiment, a further reduction of a gate leakage current is possible.

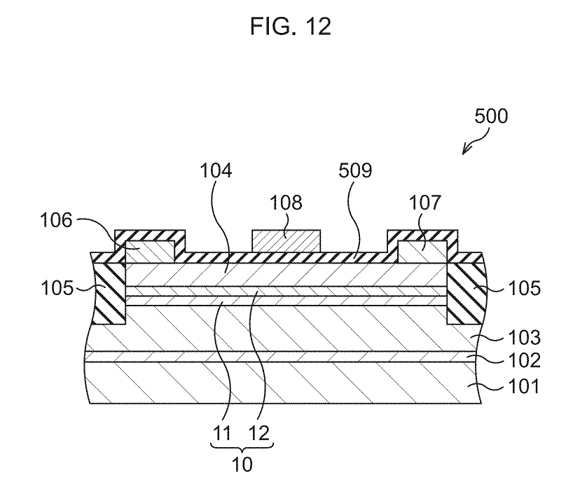

Next, a method of manufacturing the compound semiconductor device according to the fifth embodiment will be described. FIG. 13A and FIG. 13B are process-by-process sectional views illustrating the method of manufacturing the compound semiconductor device according to the fifth embodiment.

First, as illustrated in FIG. 13A, the processes up to the formation of the source electrode 106 and the drain electrode 107 are performed in the same manners as in the first embodiment. Then, the insulating film 509 is formed over the barrier layer 104 so as to cover the source electrode 106 and the drain electrode 107. The insulating film 509 may be formed by, for example, an ALD method, a PECVD method, or a sputtering method. When an aluminum oxide film is formed as the insulating film 509, the ALD method is preferable. Thereafter, as illustrated in FIG. 13B, the gate electrode 108 is formed on the insulating film 509. The gate electrode 108 may be formed by a lift-off method as in the first embodiment.

Then, a protective film, wiring, and others are formed as required to complete the compound semiconductor device.

### Sixth Embodiment

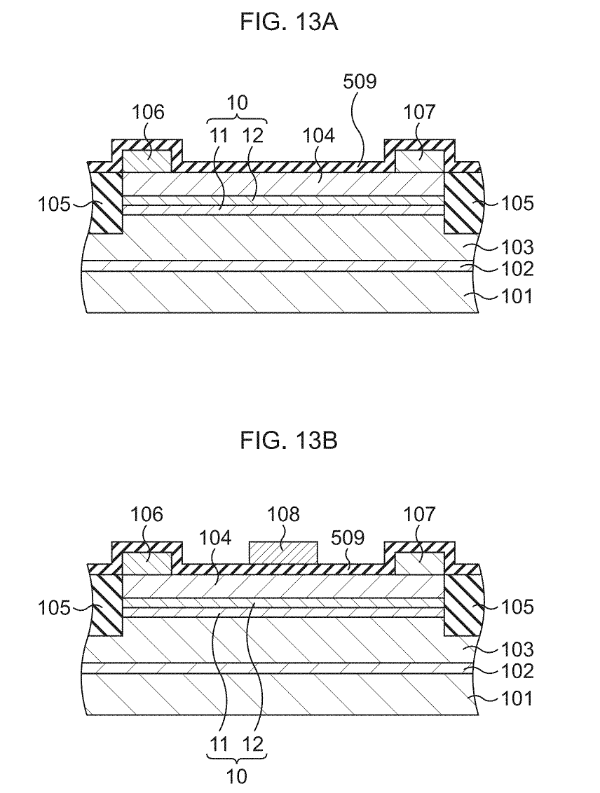

Next, a sixth embodiment will be described. The sixth embodiment relates to an example of HEMT including a compound semiconductor epitaxial substrate. FIG. 14 is a view illustrating a compound semiconductor device according to the sixth embodiment.

As illustrated in FIG. 14, a compound semiconductor device 600 according to the sixth embodiment includes, over the barrier layer 104, the insulating film 509 instead of the insulating film 109. The other structure is the same as that of the second embodiment.

In the sixth embodiment, the substrate 101, the nucleation layer 102, the channel layer 103, the spacer structure 20, and the barrier layer 104 are included in the compound semiconductor epitaxial substrate.

The sixth embodiment adopts the MIS gate structure, while the second embodiment adopts the Schottky gate structure. Therefore, according to the sixth embodiment, a further reduction of a gate leakage current is possible.

### Seventh Embodiment

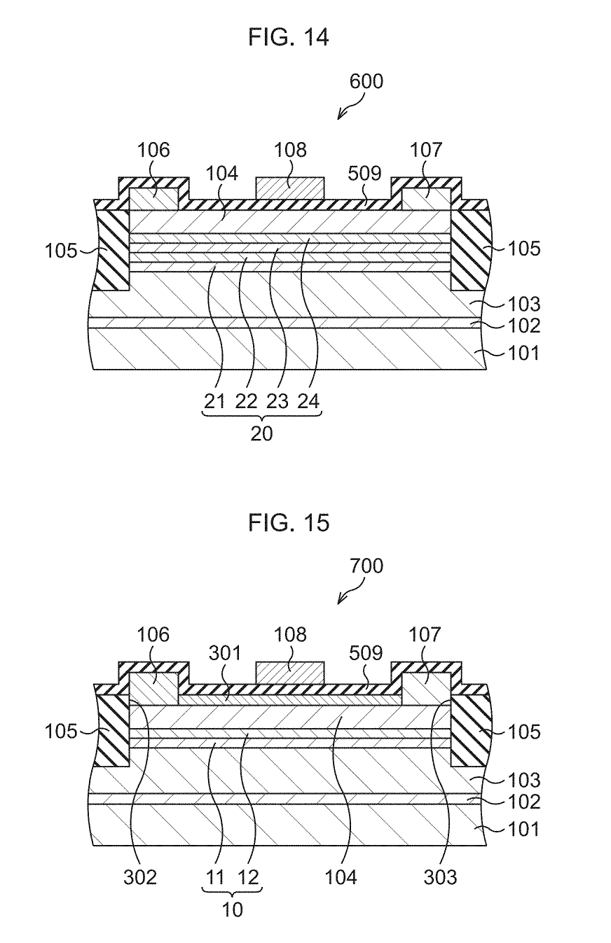

Next, a seventh embodiment will be described. The seventh embodiment relates to an example of HEMT including a compound semiconductor epitaxial substrate. FIG. 15 is a view illustrating a compound semiconductor device according to the seventh embodiment.

As illustrated in FIG. 15, a compound semiconductor device 700 according to the seventh embodiment includes, over the cap layer 301, the insulating film 509 instead of the insulating film 109. The other structure is the same as that of the third embodiment.

In the seventh embodiment, the substrate 101, the nucleation layer 102, the channel layer 103, the spacer structure 10, the barrier layer 104, and the cap layer 301 are included in the compound semiconductor epitaxial substrate.

The seventh embodiment adopts the MIS gate structure, while the third embodiment adopts the Schottky gate structure. Therefore, according to the seventh embodiment, a further reduction of a gate leakage current is possible.

### Eighth Embodiment

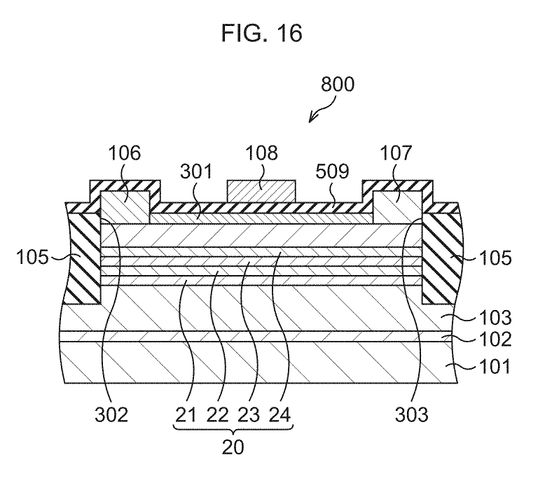

Next, an eighth embodiment will be described. The eighth embodiment relates to an example of HEMT including a compound semiconductor epitaxial substrate. FIG. 16 is a view illustrating a compound semiconductor device according to the eighth embodiment.

As illustrated in FIG. 16, a compound semiconductor device 800 according to the eighth embodiment includes, over the cap layer 301, the insulating film 509 instead of the insulating film 109. The other structure is the same as that of the fourth embodiment.

In the eighth embodiment, the substrate 101, the nucleation layer 102, the channel layer 103, the spacer structure 20, the barrier layer 104, and the cap layer 301 are included in the compound semiconductor epitaxial substrate.

The eighth embodiment adopts the MIS gate structure, while the fourth embodiment adopts the Schottky gate structure. Therefore, according to the eighth embodiment, a further reduction of a gate leakage current is possible.

### Ninth Embodiment

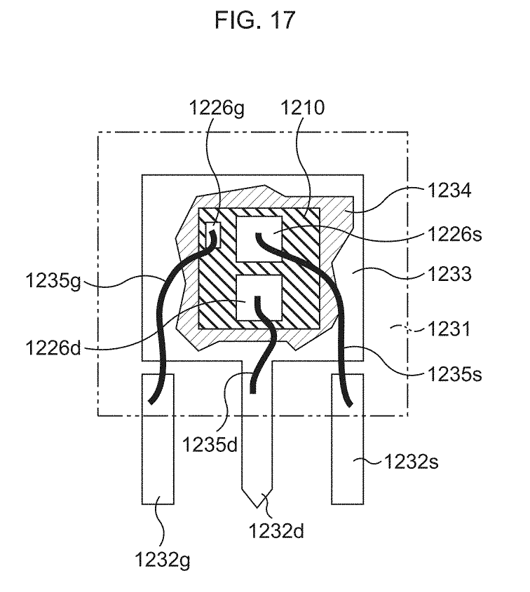

Next, a ninth embodiment is described. The ninth embodiment relates to a discrete package of a compound semiconductor device including HEMTs. FIG. 17 is a view illustrating the discrete package according to the ninth embodiment.

In the ninth embodiment, as illustrated in FIG. 17, a back surface of a HEMT chip 1210 of the compound semiconductor device including HEMTs according to any one of the first to eighth embodiments is fixed on a land (die pad) 1233, using a die attaching agent 1234 such as solder. One end of a wire 1235d such as an Al wire is bonded to a drain pad 1226d, to which the drain electrode 107 is connected, and the other end of the wire 1235d is bonded to a drain lead 1232d integral with the land 1233. One end of a wire 1235s such as an Al wire is bonded to a source pad 1226s, to which the source electrode 106 is connected, and the other end of the wire 1235s is bonded to a source lead 1232s separated from the land 1233. One end of a wire 1235g such as an Al wire is bonded to a gate pad 1226g, to which the gate electrode 108 is connected, and the other end of the wire 1235g is bonded to a gate lead 1232g separated from the land 1233. The land 1233, the HEMT chip 1210 and so forth are packaged with a molding resin 1231, so as to project outwards a portion of the gate lead 1232g, a portion of the drain lead 1232d, and a portion of the source lead 1232s.

The discrete package may be manufactured by the procedures below, for example. First, the HEMT chip 1210 is bonded to the land 1233 of a lead frame, using a die attaching agent 1234 such as solder. Next, with the wires 1235g, 1235d and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame, respectively, by wire bonding. The molding with the molding resin 1231 is conducted by a transfer molding process. The lead frame is then cut away.

### Tenth Embodiment

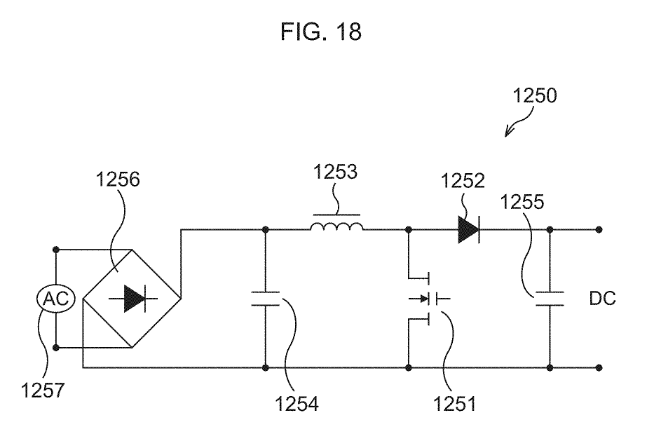

Next, a tenth embodiment is described. The tenth embodiment relates to a PFC (power factor correction) circuit equipped with a compound semiconductor device including HEMTs. FIG. 18 is a wiring diagram illustrating the PFC circuit according to the tenth embodiment.

A PFC circuit 1250 has a switching element (transistor) 1251, a diode 1252, a choke coil 1253, capacitors 1254 and 1255, a diode bridge 1256, and an AC power source (AC) 1257. The drain electrode of the switching element 1251, the anode terminal of the diode 1252, and one terminal of the choke coil 1253 are connected with each other. The source electrode of the switching element 1251, one terminal of the capacitor 1254, and one terminal of the capacitor 1255 are connected with each other. The other terminal of the capacitor 1254 and the other terminal of the choke coil 1253 are connected with each other. The other terminal of the capacitor 1255 and the cathode terminal of the diode 1252 are connected with each other. A gate driver is connected to the gate electrode of the switching element 1251. The AC 1257 is connected between both terminals of the capacitor 1254 via the diode bridge 1256. A DC power source (DC) is connected between both terminals of the capacitor 1255. In the embodiment, the compound semiconductor device including HEMTs according to any one of the first to eighth embodiments is used as the switching element 1251.

In the method of manufacturing the PFC circuit 1250, for example, the switching element 1251 is connected to the diode 1252, the choke coil 1253 and so forth with solder, for example.

### Eleventh Embodiment

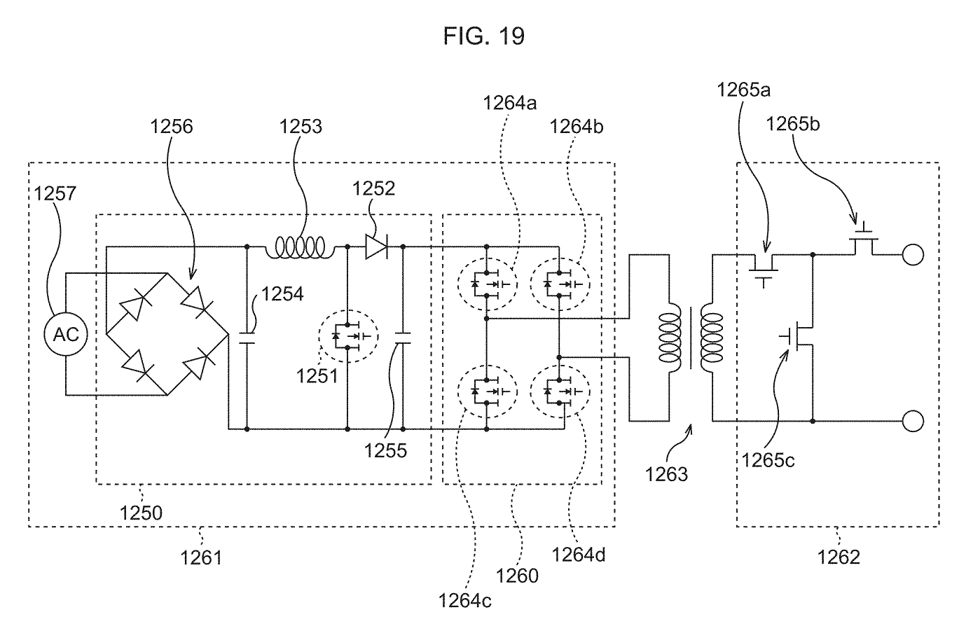

Next, an eleventh embodiment is described. The eleventh embodiment relates to a power supply apparatus equipped with a compound semiconductor device including HEMTs. FIG. 19 is a wiring diagram illustrating the power supply apparatus according to the eleventh embodiment.

The power supply apparatus includes a high-voltage, primary-side circuit 1261, a low-voltage, secondary-side circuit 1262, and a transformer 1263 arranged between the primary-side circuit 1261 and the secondary-side circuit 1262.

The primary-side circuit 1261 includes the PFC circuit 1250 according to the tenth embodiment, and an inverter circuit, which may be a full-bridge inverter circuit 1260, for example, connected between both terminals of the capacitor 1255 in the PFC circuit 1250. The full-bridge inverter circuit 1260 includes a plurality of (four, in the embodiment) switching elements 1264a, 1264b, 1264c and 1264d.

The secondary-side circuit 1262 includes a plurality of (three, in the embodiment) switching elements 1265a, 1265b and 1265c.

In the embodiment, the compound semiconductor device including HEMTs according to any one of the first to eighth embodiments is used for the switching element 1251 of the PFC circuit 1250, and for the switching elements 1264a, 1264b, 1264c and 1264d of the full-bridge inverter circuit 1260. The PFC circuit 1250 and the full-bridge inverter circuit 1260 are components of the primary-side circuit 1261. On the other hand, a silicon-based general MIS-FET (field effect transistor) is used for the switching elements 1265a, 1265b and 1265c of the secondary-side circuit 1262.

### Twelfth Embodiment

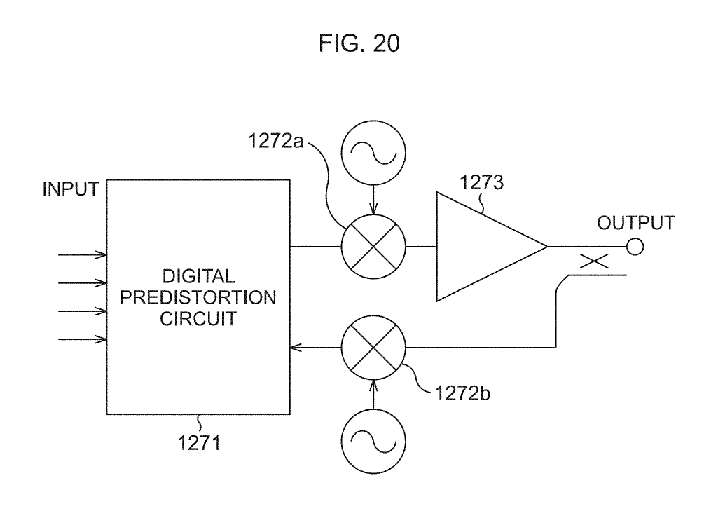

Next, a twelfth embodiment is explained. The twelfth embodiment relates to an amplifier equipped with a compound semiconductor device including HEMTs. FIG. 20 is a wiring diagram illustrating the amplifier according to the twelfth embodiment.

The amplifier includes a digital predistortion circuit 1271, mixers 1272a and 1272b, and a power amplifier 1273.

The digital predistortion circuit 1271 compensates non-linear distortion in input signals. The mixer 1272a mixes the input signal having the non-linear distortion already compensated, with an AC signal. The power amplifier 1273 includes the compound semiconductor device including HEMTs according to any one of the first to eighth embodiments, and amplifies the input signal mixed with the AC signal. In the embodiment, the signal on the output side may be mixed, upon switching, with an AC signal by the mixer 1272b, and may be sent back to the digital predistortion circuit 1271. The amplifier may be used as a high-frequency amplifier or a high-output amplifier.

In any of the embodiments, the substrate may be a silicon carbide (SiC) substrate, a sapphire substrate, a silicon substrate, a diamond substrate, a GaN substrate, a GaAs substrate, or the like. The substrate may be conductive, semi-insulative, or insulative.

The structures of the gate electrode, the source electrode, and the drain electrode are not limited to those in the above-described embodiments. For example, they each may be formed of a single layer. Further, a method of forming them is not limited to the lift-off method. Moreover, the heat treatment after the formation of the source electrode and the drain electrode may be omitted, if the ohmic characteristics can be obtained. The gate electrode may contain Pd and/or Pt in addition to Ni and Au. The numbers of gate electrodes, source electrodes and drain electrodes are not limited to those in the above-described embodiments.

According to the above-described compound semiconductor device and so on, it is possible to obtain the barrier layer excellent in surface flatness because the appropriate spacer structure is included.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
a substrate;
a channel layer formed over the substrate;
a spacer structure formed over the channel layer;
a barrier layer of Inₓ₁Al_{y1}Ga_{1-x1-y1}N (0≤x1<0.20, 0<y1≤1) formed over the spacer structure; and
a gate electrode, a source electrode, and a drain electrode which are formed over the barrier layer,
wherein the spacer structure comprises:
a first spacer layer of Alₓ₂Ga₁₋ₓ₂N (0<x2<1) formed over the channel layer; and
a second spacer layer of GaN formed over the first spacer layer.

2. The compound semiconductor device according to claim 1, wherein the spacer structure includes a plurality of stacks of the first spacer layer and the second spacer layer.

3. The compound semiconductor device according to claim 1, wherein the channel layer is a GaN layer.

4. The compound semiconductor device according to claim 1, wherein the second spacer layer includes a thickness of 2 nm or less.

5. The compound semiconductor device according to claim 1, comprising a cap layer of Alₓ₃Ga₁₋ₓ₃N (0≤x3<1) formed over the barrier layer.

6. The compound semiconductor device according to claim 1, comprising a gate insulating film formed between the barrier layer and the gate electrode.

7. The compound semiconductor device according to claim 1, wherein the channel layer and the barrier layer are substantially in lattice match with each other.

8. A power supply apparatus, comprising
a compound semiconductor device, wherein the compound semiconductor device comprises:
a substrate;
a channel layer formed over the substrate;
a spacer structure formed over the channel layer;
a barrier layer of Inₓ₁Al_{y1}Ga_{1-x1-y1}N (0≤x1<0.20, 0<y1≤1) formed over the spacer structure; and
a gate electrode, a source electrode, and a drain electrode which are formed over the barrier layer,
wherein the spacer structure comprises:
a first spacer layer of Alₓ₂Ga₁₋ₓ₂N (0<x2<1) formed over the channel layer; and
a second spacer layer of GaN formed over the first spacer layer.

9. An amplifier, comprising
a compound semiconductor device, wherein the compound semiconductor device comprises:
a substrate;
a channel layer formed over the substrate;
a spacer structure formed over the channel layer;
a barrier layer of Inₓ₁Al_{y1}Ga_{1-x1-y1}N (0≤x1<0.20, 0<y1≤1) formed over the spacer structure; and
a gate electrode, a source electrode, and a drain electrode which are formed over the barrier layer,
wherein the spacer structure comprises:
a first spacer layer of Alₓ₂Ga₁₋ₓ₂N (0<x2<1) formed over the channel layer; and
a second spacer layer of GaN formed over the first spacer layer.
